(19) United States
(12) Patent Application Publication
(10) Pub. No.: US 2015/0158737 A1
(43) Pub. Date: Jun. 11, 2015

(54) PRODUCTION METHOD FOR ZINC OXIDE HAVING IMPROVED POWER FACTOR DUE TO INCREASED GALLIUM DOPING

(71) Applicants: Soon Mok CHOI, (US); Won Seon SEO, Seoul (KR); Kwang Hee JUNG, Seoul (KR)

(72) Inventors: Soon Mok Choi, Seoul (KR); Won Seon Seo, Seoul (KR); Kwang Hee Jung, Seoul (KR)

(73) Assignee: KOREA INSTITUTE OF CERAMIC ENGINEERING AND TECHNOLOGY, Seoul (KR)

(21) Appl. No.: 14/405,156

(22) PCT Filed: Oct. 18, 2012
(86) PCT No.: PCT/KR2012/008516

§ 371 Date: Dec. 3, 2014

(30) Foreign Application Priority Data
Jun. 5, 2012 (KR) 10-2012-0060654

(51) Int. Cl. C01G 9/02; H01L 35/22

(52) U.S. Cl. CPC C01G 9/02; H01L 35/22; C01P 2006/40

(57) ABSTRACT

The present invention relates to polycrystalline gallium-doped zinc oxide of which the power factor is improved due to increased gallium doping of same. Despite having a high carrier concentration, the Seebeck coefficient of Zn_{0.985}Ga_{0.015}O is higher than that of Zn_{0.990}Ga_{0.010}O, and this arises because of the effect of the density-of-states (DOS) effective mass. A steady increase in compression stress following gallium substitution occurs in the base portion of the conduction band DOS. The solubility limit of gallium in the zinc oxide matrix is increased because a low firing temperature accelerates chemical compression. Single phase n-type Zn_{0.985}Ga_{0.015}O exhibits a power factor of 12.5 μWcm⁻¹K⁻².

### TECHNICAL FIELD

The present invention relates to a method of producing zinc oxide having improved power factor due to increased gallium doping, and more particularly, to a method of producing zinc oxide (ZnO) having improved power factor due to an increase in gallium (Ga) doping, which includes: mixing Zn, Ga or a compound including the same as a starting material, thus preparing a mixture; molding the mixture into a molded body, which is then primarily sintered, thus producing a first sintered body; and subjecting the first sintered body to grinding, molding and secondary sintering, thus producing a second sintered body, wherein Ga-doped ZnO is synthesized via primary sintering and primary sintering is carried out at 900˜1100° C.

### BACKGROUND ART

Thermoelectric performance of a material is evaluated by ZT value that is a dimensionless thermoelectric figure of merit, and the ZT value may be represented by S²σTκ⁻¹ where S is the Seebeck coefficient at an absolute temperature T, σ is the electrical conductivity, T is the absolute temperature, and κ is the thermal conductivity. Recently, many researchers have reported that crystalline structures can be formed into a nano size so as to enable scattering of phonons within a range that does not affect the power factor (S²σ) of a thermoelectric material, thereby reducing thermal conductivity. The power factor may be improved by maximizing electrical power density, which is associated with an increase in Seebeck coefficient. Based on the fact that the Seebeck coefficient and the electrical conductivity are inversely proportional, a high Seebeck coefficient may reduce a carrier density, thus decreasing electrical conductivity.

In place of the method of controlling the electrical power density, a method of increasing Seebeck coefficient may include a chemical compression process. The density of states (DOS) g(E) may be increased by generating compressive stress on a unit cell via doping of external atoms, thereby enabling an increase in the Seebeck coefficient.

Thermoelectric oxide including a ZnO matrix, such as ZnO doped with aluminum (Al) or Ga, has been evaluated as a promising material for a high-temperature thermoelectric power generation system. This is because it is stable at high temperature. Al-doped ZnO having a non-nanostructure has a high ZT value of 0.33 at 1073K, but still exhibits low performance compared to a recent thermoelectric material such as lead telluride (PbTe). This is considered to be due to high lattice thermal conductivity and low power factor.

Also, the lattice thermal conductivity of Al-doped ZnO has been recently reported to be lowered significantly depending on the nanostructure of crystal. As such, the ZT value shows 0.44 at 1000K. Meanwhile, the power factor of the thermoelectric material may be enhanced via chemical compression, making it possible to obtain higher DOS in the lower portion of the conduction band.

Since zinc oxide is a polar semiconductor, the band structure thereof may effectively vary by virtue of introduction of inplane stress. The Seebeck coefficient may be improved under lattice compression, due to an increase in DOS effective mass (md*). Accordingly, the chemical compression process using site element substitution may be effective at improving the power factor of zinc oxide.

Al and Ga may play a role as a dopant that is very useful in changing the crystal structure of ZnO. This is because Al³⁺ has an ionic radius of 53.5 pm, Ga³⁺ has an ionic radius of 62.0 pm and Zn²⁺ has an ionic radius of 74.0 pm, which are similar to each other, thus facilitating the element substitution. Furthermore, the doped Al³⁺ and Ga³⁺ may function as an n-type dopant to thus produce an electron carrier for generating a thermoelectric effect.

However, the solubility of a trivalent cation such as Al³⁺ or Ga³⁺ added to ZnO is limited by the formation of a second phase. When the trivalent ion is doped in a large amount, a second phase such as ZnAl₂O₄, ZnGa₂O₄ and Zn₉Ga₂O₁₂ is inevitably formed, undesirably deteriorating the carrier transport performance of zinc oxide doped with Al and Ga. The upper limit of the solubility of Al³⁺ is reported to be about 2 at. % (atomic %), whereas the solubility of Ga³⁺ for single-phase zinc oxide is greatly limited to 1 at. %. As Ga³⁺ replaces Zn²⁺, an electron carrier is produced. In this case, even when the sufficient carrier concentration is supported, maximum thermoelectric performance cannot be exhibited, due to low Ga solubility, undesirably causing problems where thermoelectric performance of Ga-doped ZnO is inferior to that of Al-doped ZnO.

### DISCLOSURE

### Technical Problem

Accordingly, the present invention has been made keeping in mind the problems encountered in the related art, and an object of the present invention is to provide a ZnO-based thermoelectric material having improved thermoelectric power factor by increasing the amount of doped Ga in a ZnO matrix.

Another object of the present invention is to provide production of a sintered body having high density while enabling the preparation of single-phase Zn—Ga-based oxide despite doping of Ga by applying two-step sintering at a temperature lower than a conventional sintering temperature.

Upon primary sintering (synthesis) at low temperature, doping of Ga in a larger amount is experimentally possible. As such, formation of a second phase is inhibited at a given temperature. Also, secondary sintering may be performed using a spark plasma sintering (SPS) process having very short holing time at relatively high temperature compared to the primary sintering temperature, so that the formation of the second phase may be inhibited in a given temperature range.

### Technical Solution

In order to accomplish the above objects, the present invention provides a method of producing zinc oxide (ZnO) having improved power factor due to increased gallium doping, comprising: mixing zinc (Zn), gallium (Ga) or a compound including Zn or Ga as a starting material, thus preparing a mixture; molding the mixture into a molded body and subjecting the molded body to primary sintering, thus manufacturing a first sintered body; and subjecting the first sintered body to grinding, molding and secondary sintering, thus manufacturing a second sintered body, wherein Ga-doped ZnO is synthesized by primary sintering, and primary sintering is performed at 900˜1100° C.

Preferably, the second sintered body is manufactured by a spark plasma sintering process at a pressure of 50˜100 MPa and a sintering temperature of 1000˜1200° C. for a holding time of 10 min or less.

Preferably, the first sintered body comprises a compound represented by Zn₁₋ₓGaₓO where x is in the range of 0.18 or less but exceeding zero and Zn₁₋ₓGaₓO is a single phase.

In addition, the present invention provides zinc oxide having improved power factor due to increased Ga doping, which is produced by the method as above and comprises a compound represented by Zn₁₋ₓGaₓO where x is in the range of 0.18 or less but exceeding zero and Zn₁₋ₓGaₓO is a single phase.

### Advantageous Effects

According to the present invention, Ga doping can be further increased in a ZnO matrix in the range of maintaining thermoelectric properties that can be commercialized.

Also, a sintering temperature lower than a conventional sintering temperature is applied, and a two-step sintering process is introduced, thus increasing both density and power factor of Ga-doped ZnO depending on an increase in Ga doping.

### DESCRIPTION OF DRAWINGS

FIG. 1(a) illustrates the X-ray pattern of Zn₁₋ₓGaₓO (x=0.015, 0.020) according to an embodiment of the present invention including a Zn_{0.985}Ga_{0.015}O sintered body sample manufactured by a SPS process, and FIG. 1(b) illustrates a- and c-axis lattice parameters in a Ga-doped function;

FIG. 2(a) illustrates the electrical conductivity a of Zn₁₋ₓGaₓO (x=0.005, 0.010, 0.015, 0.020) according to an embodiment of the present invention depending on the temperature (wherein the internal plot is correlation between Hall mobility (μ_{Hall}) at 50° C. and carrier concentration (nₑ)), FIG. 2(b) illustrates the Seebeck coefficient S thereof and FIG. 2(c) illustrates the power factor thereof; and

FIG. 3(a) illustrates the DOS effective mass (md*) of Zn₁₋ₓGaₓO (x=0.005, 0.010, 0.015, 0.020) depending on the Ga doping (wherein the internal plot is md* depending on the temperature), and FIG. 3(b) illustrates md* in c/a lattice ratio function.

### BEST MODE

Hereinafter, a detailed description will be given of preferred embodiments of the present invention with reference to the appended drawings.

In the present invention, sintering conditions are adjusted to increase the solubility of Ga. Particularly, the sintering temperature, sintering process, and holding time are adjusted, and thereby the extent of chemical compression in a ZnO matrix and the carrier concentration may be optimized, ultimately achieving high power factor.

In the present invention, a Zn₁₋ₓGaₓO (x=0.005, 0.010, 0.015) single-phase thermoelectric material is prepared. With the goal of evaluating whether high Ga doping in ZnO may have a great influence on the electron transport parameter including md*, the values S and σ are measured, and thereby an enhancement in thermoelectric performance may be estimated.

Among Ga-doped samples, Zn_{0.985}Ga_{0.015}O shows significantly improved power factor. Furthermore, chemical compression may be created via Ga substitution according to the present invention.

Typically, Ga is doped under the condition that the upper limit of the value x is 0.01. The reason why the upper limit of Ga doping cannot be further increased is that an increase in the Ga doping results in raised synthesis temperature to thus increase a probability of forming a second phase. Hence, the present invention is intended to perform a doping process up to the value x of 0.018, which has not been reported to date, without formation of the second phase.

### Preparative Example

In the present invention, Zn₁₋ₓGaₓO (x=0.005, 0.010, 0.015, 0.020) was prepared from ZnO and Ga₂O₃ powder as starting materials via a solid-phase reaction method.

The starting material may include Zn, Ga-containing compounds other than Ga₂O₃, or Ga alone, and any starting material able to produce Zn₁₋ₓGaₓO may be used, but the present invention is not limited thereto.

The Zn₁₋ₓGaₓO powder prepared by a solid-phase reaction method was weighed at an appropriate ratio, and mixed via ball milling with an ethanol solvent and zirconia balls as a mixing medium.

Thereafter, the resulting mixture was dried, and the dried mixture was pressed at a pressure of 200 MPa for 5 min using cold isostatic pressing (CIP). The molded sample was primarily sintered at 1100° C. for 10 hr in a nitrogen atmosphere, thus manufacturing a sintered body sample.

Upon primary sintering, the sintering temperature is determined according to an embodiment of the present invention, and is preferably set to the range of 900˜100° C. If the sintering temperature is lower than 900° C., unreacted material may be left behind. In contrast, if the sintering temperature is higher than 1100° C., ZnGa₂O₄ spinel as a second phase is formed. Thus, there is a critical significance in the upper and the lower limit of the primary sintering temperature.

Thereafter, the sintered body sample was ground, and the ground powder was press sintered for a holding time of less than 10 min using a spark plasma sintering (SPS) process as a secondary sintering process under conditions of a pressure of 70 MPa, a temperature of 1000° C. and a holding time of 5 min, thus manufacturing a dense sintered body.

Upon secondary sintering, the sintering temperature is determined according to an embodiment of the present invention, and is preferably set to the range of 1000˜1200° C. If the sintering temperature is lower than 1000° C., the density of the sintered body is not sufficient. In contrast, if the sintering temperature is higher than 1200° C., ZnGa₂O₄ spinel may be formed as a second phase. Thus, there is a critical significance in the upper and the lower limit of the secondary sintering temperature.

The reason why the spinel formation temperature is different upon primary sintering and secondary sintering is as follows. Specifically, although the primary sintering temperature is slightly low, the holding time is typically very long, and thus a probability of forming the spinel as a second phase is high when such a temperature falls outside of the upper limit. Also, since the holding time is short upon secondary sintering, the second phase may not be formed so long as the secondary sintering temperature that is higher than the primary sintering temperature falls in the upper limit range as above.

### EXAMPLE

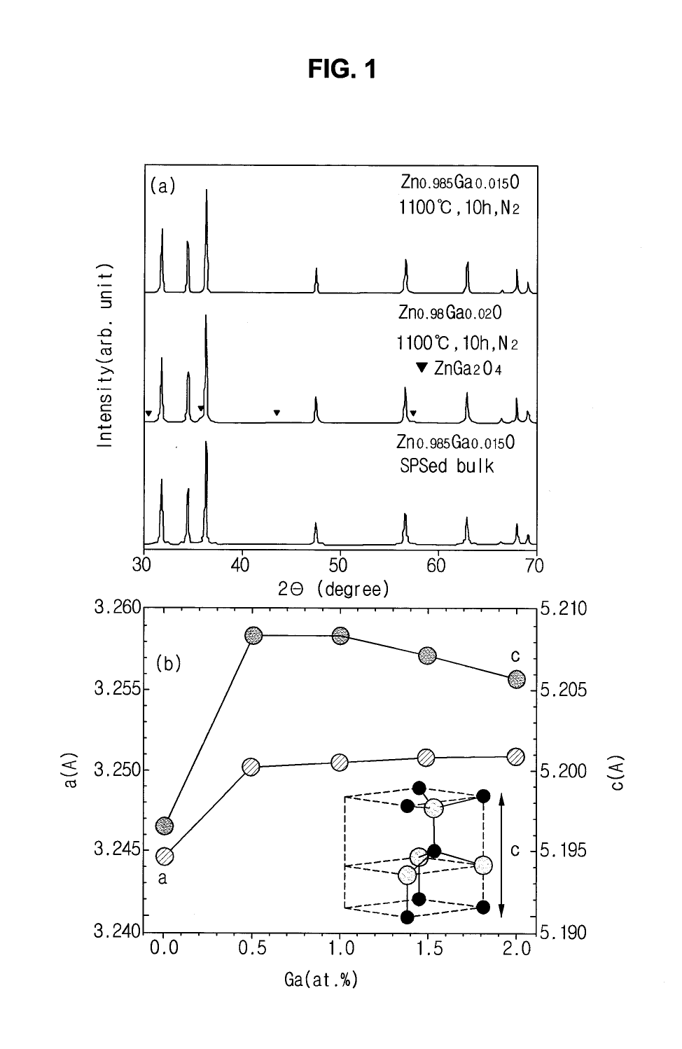

FIG. 1 illustrates the results of X-ray analysis of Zn_{0.985}Ga₀₀₁₅O and Zn_{0.980}Ga_{0.020}O samples sintered at 1100° C. Though the peak of the second phase was not detected in Zn_{0.985}Ga_{0.015}O, a small amount of spinel ZnGa₂O₄ was detected as the second phase in Zn_{0.980}Ga_{0.014}O.

The production of single-phase wurtzite in 1.5 at. % Ga-doped ZnO (Zn_{0.985}Ga_{0.015}O) was not yet reported. This is because it is impossible to produce single-phase wurtzite without formation of the second phase such as ZnGa₂O₄ or Zn₉Ga₂O₁₂ by conventional techniques. Specifically, due to a high sintering temperature of 1350° C. or more corresponding to the sintering condition to manufacture the sample having a theoretical density, spinel ZnGa₂O₄ or Zn₉Ga₂O₁₂ having a regularly modulated-homologous structure was inevitably formed. This is because Ga³⁺ has specific properties in which it is located at 6- or 4-coordination site of Ga₂O₃.

The solubility limit of Ga in ZnO falls in the range of 1 at. % to 1.5 at. % depending on the solid-phase reaction temperature and the atmosphere. However, Zn_{0.985}Ga_{0.015}O sintered at 1100° C. had very weak mechanical strength and low carrier transport performance, due to low density of less than 80%.

To overcome such a low density, the sintered body was ground, and the resulting powder was press sintered using a SPS process under conditions of a pressure of 70 MPa, a temperature of 1000° C. and a holding time of 5 min, so that it became dense.

The final density of the sample sintered using a SPS process was measured to be about 95% of the theoretical density. As illustrated in FIG. 1(a), the Zn₁₋ₓGaₓO (x=0.005, 0.010, 0.015) sample was maintained in a single phase even after the SPS process.

Although not specifically shown herein, the single phase appeared up to the value of 0.018 based on the actual testing results. If the value x exceeded the above upper limit, a tendency of forming the second phase and a tendency of not forming the second phase were present together. Therefore, the single phase according to the present invention can be considered to be reproducibly formed under the condition that the upper limit of the value x is 0.018.

The single phase close to the theoretical density may be sufficiently ensured by adjusting the process parameters. The single-phase sample including Zn_{0.985}Ga_{0.015}O is estimated to have greatly enhanced electrical conductivity because the amount of doped donor may be increased. According to the present invention, Ga doping may be further increased in the range that enables the production of the single phase, compared to conventional techniques.

More importantly, in the single-phase Zn₁₋ₓGaₓO, it is possible to induce lattice compression by substituting Zn²⁺ ions with Ga³⁺ ions. The Seebeck coefficient is considered to increase due to lattice compression. As such, the density of states may change. Some researchers have performed Rietveld refinement (RIETAN 2000 program) to evaluate structural changes due to Ga doping. The reliable factor R_{wp} had a value of 9˜14% in all the compounds. The results of crystallographic data are illustrated in FIG. 1(b).

The lattice parameter a was almost uniform, whereas the lattice parameter c was gradually decreased in proportion to an increase in the amount of Ga, and thus chemical compression was caused by doping of Ga. Based on the results of lattice compression in a c-axis direction, an increase in the Seebeck coefficient may be estimated to have no relation with the carrier concentration.

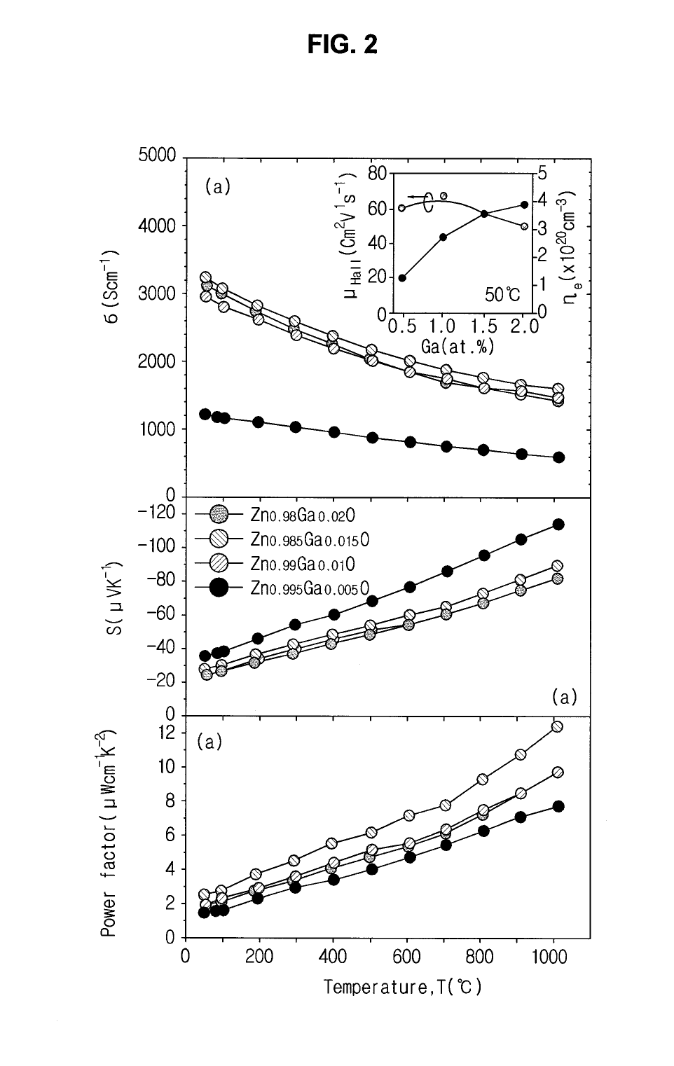

The values S and σ were measured in the temperature range of 50˜100° C. by applying both a steady-state method and a four-probe method. For Zn₁₋ₓGaₓO (x=0.005, 0.010, 0.015, 0.020) of FIG. 2, (a) shows the value σ and (b) shows the value S.

Ga-doped ZnO has the value σ that is gradually decreased depending on temperature, and thus refers to a degenerate semiconductor. The additional carrier transport properties including carrier concentration (nₑ) and Hall mobility (μ_{Hall}) were measured by Van der Pauw configuration in a vacuum. The results are shown in FIG. 2(a).

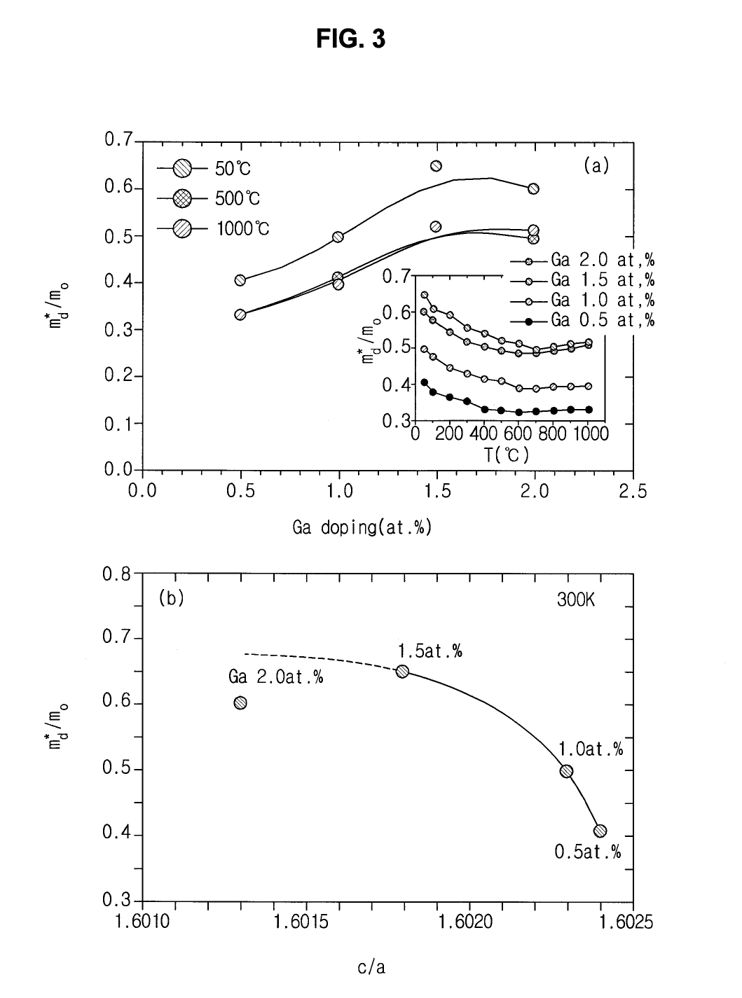

The value nₑ of the sample fell in the range of from 1.26×10²⁰ cm⁻³ for 0.5 at. % Ga-doped sample to 3.89×10²⁰ cm⁻³ for 2.0 at. % Ga-doped sample. The μ_{Hall} did not greatly vary depending on the amount of Ga. However, the value μ_{Hall of Zn}_{0.980}Ga_{0.020}O at 50° C. was slightly decreased to 50.1 cm²V⁻s⁻¹ by carrier scattering due to the presence of the second phase. The value S was negative in all the compounds, which means that the sample was an n-type conductor, and |S| was monotonically increased in proportion to an increase in temperature. As such, it is noted that Zn_{0.990}Ga_{0.010}O (nₑ˜3.58×10²⁰ cm⁻³) exhibits higher carrier concentration but |S| is higher in Zn_{0.985}Ga_{0.015}O (nₑ˜2.78×10²⁰ cm⁻³). To examine the cause of high |S| in Zn_{0.985}Ga_{0.015}O, the value md* was calculated using the measured values S and nₑ. The results are shown in FIG. 3(a).

Also, md* is important for determining the value S, which may be deduced from the following equation. As such, the corresponding composition is supposed to be a degenerate parabolic band semiconductor.

$$S = \frac{8 {π}^{2} {k}_{b}^{2} T}{3 {qh}^{2}} {{m}_{d}^{*} ( \frac{π}{3 n} )}^{2 / 3} \qquad ( 1 )$$

In this equation, k_{B}, h and e are Boltzmann constant, Planck constant, and unit charge, respectively. FIG. 3(b) illustrates md* represented as a c/a ratio function at 50° C.

The value md* is in the range of from 0.41 m₀ (Zn_{0.995}Ga_{0.005}O) to 0.65 m₀ (Zn_{0.985}Ga_{0.015}O). It was reported that the value md* of ZnO is closely related with the crystalline structure, especially inplane stress. In Al-doped ZnO, md* was increased in proportion to a decrease in the c/a ratio, thus causing non-parabolicity of the band structure due to the lattice compression.

Therefore, an increase in md* of Zn_{0.985}Ga_{0.015}O may be inferred from structural modification and optimal carrier concentration. FIG. 3(c) illustrates the temperature dependence of the power factor for Zn₁₋ₓGaₓO (x=0.005, 0.010, 0.015, 0.020). The power factor was significantly increased depending on an increase in the temperature in all the compositions. Generally, the power factor was in the range of 7.7˜12.5 μWcm⁻¹K⁻² at 1000° C., and the maximum power factor was 12.5 μWcm⁻¹K⁻² at the same temperature for 1.5 at. % Ga-doped ZnO. The improved power factor led to an increase in the solubility of Ga, thereby obtaining high DOS via chemical compression.

Briefly, Zn₁₋ₓGaₓO (x=0.005, 0.010, 0.015, 0.020) polycrystalline samples are controlled so as to react at low temperature, and are produced using a spark plasma sintering process. Zn_{0.985}Ga_{0.015}O shows the greatly increased |S| due to the increased md* via chemical compression. Thereby, the effect of the crystalline structure on carrier transport performance can be confirmed, and the effective method of controlling the lattice structure includes substituting the Zn²⁺ site with a small amount of M³⁺ dopant to increase |S|. Accordingly, thermoelectric performance of the ZnO-based thermoelectric material is favorably improved.

1. A method of producing zinc oxide (ZnO) having an improved power factor due to increased gallium doping, comprising:
mixing zinc (Zn), gallium (Ga) or a compound including Zn or Ga as a starting material, thus preparing a mixture;
molding the mixture into a molded body and subjecting the molded body to primary sintering, thus manufacturing a first sintered body; and
subjecting the first sintered body to grinding, molding and secondary sintering, thus manufacturing a second sintered body,
wherein Ga-doped ZnO is synthesized by the primary sintering, and the primary sintering is performed at 900˜1100° C.

2. The method of claim 1, wherein the second sintered body is manufactured by a spark plasma sintering process at a pressure of 50˜100 MPa and a sintering temperature of 1000˜1200° C. for a holding time of 10 min or less.

3. The method of claim 1, wherein the first sintered body comprises a compound represented by Zn₁₋ₓGaₓO where x is in a range of 0.18 or less but exceeding zero and Zn₁₋ₓGaₓO is a single phase.

4. A zinc oxide having an improved power factor due to increased gallium doping, which is produced by the method of claim 1 and comprises a compound represented by Zn₁₋ₓGaₓO where x is in a range of 0.18 or less but exceeding zero and Zn₁₋ₓGaₓO is a single phase.
